(19) United States
(12) Patent Application Publication
(10) Pub. No.: US 2017/0146711 A1
(43) Pub. Date: May 25, 2017

(54) RAMAN EDGE FILTER IN DEEP-UV RANGE AND METHOD OF MANUFACTURING THE SAME

(71) Applicant: AGENCY FOR DEFENSE DEVELOPMENT, Daejeon (KR)

(72) Inventors: Yeon-Chul HA, Daejeon (KR); Jae-Hwan LEE, Daejeon (KR); Young-Su JEONG, Daejeon (KR); Sun-Kyung CHOI, Sejong (KR); Young-Jin KOH, Yongin-si (KR)

(21) Appl. No.: 15/168,395

(22) Filed: May 31, 2016

(30) Foreign Application Priority Data
Nov. 24, 2015 (KR) 10-2015-0164780

(51) Int. Cl. G02B 5/28; C23C 14/10; C23C 14/46; C23C 14/08; G01J 3/02; G01J 3/44

(52) U.S. Cl. CPC G02B 5/283; G01J 3/0205; G01J 3/4412; G02B 5/285; C23C 14/46; C23C 14/081; C23C 14/10

(57) ABSTRACT

A Raman edge filter and a method of manufacturing the same, wherein in order to obtain a Raman spectrum for compound analysis in a Raman spectrometer using a deep-ultraviolet ray (UV) laser, the Raman edge filter functions to eliminate a deep-UV laser wavelength, which is a light source, and to transmit Raman scattered light.

### CROSS-REFERENCE TO RELATED APPLICATION

This application claims priority to Korean Patent Application No. 10-2015-0164780 filed on Nov. 24, 2015, which is incorporated herein by reference in its entirety.

### BACKGROUND OF THE INVENTION

1. Technical Field

The present invention relates to a Raman edge filter and, more particularly, to a Raman edge filter and a method of manufacturing the same, wherein, in order to obtain a Raman spectrum for compound analysis in a Raman spectrometer using a deep-ultraviolet ray (UV) laser, the Raman edge filter functions to remove a deep-UV laser wavelength, which is a light source, and to transmit Raman scattered light.

In particular, the present invention relates to the design and fabrication of a thin film for a Raman edge filter that enables Raman scattered light to be transmitted while removing the deep-UV laser light source to obtain a Raman spectrum in the deep-UV range.

2. Description of the Related Art

Raman spectrometry is a kind of process for identifying unidentified chemical agents. A Raman spectrometer typically used in laboratories mainly adopts a laser as the light source applied to a sample to acquire a Raman signal. A Raman edge filter is essential in order to remove light having a wavelength equal to that of the used laser and to transmit Raman scattered light because laser light is very strong relative to the Raman signal.

A Raman edge filter is configured such that a thin film, called an optical multilayer, is formed on a glass substrate, and a high-refractive-index dielectric material layer and/or a low-refractive-index dielectric material layer are formed by turns on the surface of the glass substrate. In such a configuration, reflection and/or refraction of light occur due to the difference in the refractive index, and thus light rays reflected or refracted from a plurality of interfaces overlap each other, thereby causing interference of light. Thereby, strong light and weak light are converted into transmitted light and reflected light while passing through the edge filter, so that light in the target wavelength is removed and Raman scattered light is passed.

Here, a thin film is manufactured in such a manner that ions are accelerated to a target starting material in an argon atmosphere to make gaseous atoms or molecules, which are then synthesized into a thin film on a substrate. The process using such ions, capable of minimizing the difference in vapor pressure between the constituents, is referred to as sputtering.

As for a sputtering deposition process, sputtering particles deposited on the thin film have higher energy than particles generated by heat. Due to the high energy of the sputtered particles, mobility thereof is very high, and thus a physicochemical procedure for growing a thin film on a substrate is favorably promoted.

In particular, when strong monochromatic excitation light such as a laser is applied, individual molecules have natural frequencies. A Raman spectrometer using a Raman effect, which creates such a frequency difference, is mostly utilized for material analysis. Furthermore, a Raman spectrometer essentially includes a Raman edge filter for effectively eliminating monochromatic excitation light and transmitting Raman scattered light.

Moreover, many Raman edge filters may be used in the IR, visible light and some deep-UV ranges. However, a Raman edge filter, suitable for use in effectively removing a light source in a deep-UV range (about 213 nm) of interest and transmitting Raman scattered light, has not yet been introduced.

### SUMMARY OF THE INVENTION

Accordingly, the present invention has been made keeping in mind the above problems encountered in the related art, and an object of the present invention is to provide a Raman edge filter, suitable for use in effectively removing a light source in a deep-ultraviolet ray (UV) range and transmitting Raman scattered light, and a method of manufacturing the same.

In order to accomplish the above object, the present invention provides a method of manufacturing a Raman edge filter suitable for use in effectively removing a light source in a deep-UV range and transmitting Raman scattered light.

The method of manufacturing the Raman edge filter comprises: providing a molten silica substrate, a high-refractive-index dielectric material, and a low-refractive-index dielectric material in a vacuum chamber; evacuating an inside of the chamber, and repeatedly depositing the high-refractive-index dielectric material and the low-refractive-index dielectric material by turns on a surface of the molten silica substrate using ion beam sputtering (IBS) until the number of deposited layers reaches a predetermined repeating number such that an irradiation light source wavelength in a deep-UV range is removed and light at a wavelength equal to or greater than the irradiation light source wavelength is transmitted.

As such, the high-refractive-index dielectric material may include any one selected from among LaF₃, HfO₂, Al₂O₃, and Sc₂O₂, and the low-refractive-index dielectric material may include any one selected from among SiO₂, MgF₂, and Na₃AlF₆.

Also, the repeating number may be about 200 or more.

Also, the irradiation light source wavelength may have an optical density (OD) of 6 or more, and a transmittance of about 50% or more at about +4 nm.

Also, an ion beam of the ion beam sputtering may be a Kaufman-type ion beam.

Also, the irradiation light source wavelength in the deep-UV range may be about 213 nm.

Also, the repeatedly depositing may be performed in a manner in which the high-refractive-index dielectric material is deposited at a deposition rate of about 0.4 to 1.0 (Å/sec) and the low-refractive-index dielectric material is deposited at a deposition rate of about 1 to 3 (Å/sec).

In addition, the present invention provides a Raman edge filter in a deep-UV range, comprising: a molten silica substrate; a high-refractive-index dielectric material layer formed on a surface of the molten silica substrate; and a low-refractive-index dielectric material layer formed on a surface of the high-refractive-index dielectric material layer, wherein the high-refractive-index dielectric material layer and the low-refractive-index dielectric material layer are repeatedly deposited by turns on the surface of the molten silica substrate using IBS until the number of deposited layers reaches a predetermined repeating number such that an irradiation light source wavelength in a deep-UV range is removed and light at a wavelength equal to or greater than the irradiation light source wavelength is transmitted.

According to the present invention, a UV Raman edge filter having a thin film having a large number of layers can exhibit high film durability and adhesion because the thin film is formed using IBS, unlike a thermal evaporation process, in which a thin film, which is deposited at room temperature, is not dense, and has a rough surface and poor adhesion.

Also, according to the present invention, an IBS device is configured such that, when charged gas particles (Ar, O₂) having specific energy collide with the surface of a target (Al₂O₃, SiO₂) by generating plasma in an ion source and applying voltage, atoms are ejected from the surface through momentum transfer and then deposited on a substrate. The atoms deposited through IBS have deposition energy corresponding to tens of eV or more, which is higher than that of other deposition methods, and thus the deposited thin film is denser and has higher adhesion.

Also, according to the present invention, although it is commercially utilized in the visible light range, a Raman edge filter for use in a deep-UV range (213 nm) has not been provided, and thus a filter for use in Raman spectrometry can be manufactured by depositing Al₂O₃ and SiO₂ by turns on a glass substrate using IBS.

Also, according to the present invention, in consideration of the large number of layers for a thin film, the filter can be designed and/or manufactured so as to have high thin-film durability and/or bondability using IBS and to minimize absorption by adjusting the Ar-to-O₂ ratio.

Also, according to the present invention, the filter can effectively block Rayleigh scattering of a laser beam, and is thus applicable to a Raman spectrometer in a deep-UV range (213 nm).

### BRIEF DESCRIPTION OF THE DRAWINGS

The above and other objects, features and advantages of the present invention will be more clearly understood from the following detailed description taken in conjunction with the accompanying drawings, in which:

FIG. 1 illustrates a typical IBS (Ion Beam Sputtering) device;

FIG. 2 illustrates the screen for choosing a thin-film material according to an embodiment of the present invention;

FIGS. 3A and 3B are graphs illustrating the results of optimization of a design of a thin film for the Raman edge filter;

FIG. 4 illustrates the design of a thin film for the Raman edge filter according to an embodiment of the present invention;

FIG. 5 is a graph illustrating the performance of a Raman filter according to an embodiment of the present invention; and

FIG. 6 is a flowchart illustrating the process of manufacturing a Raman edge filter according to an embodiment of the present invention.

### DESCRIPTION OF THE SPECIFIC EMBODIMENTS

Reference will now be made in detail to various embodiments of the present invention, specific examples of which are illustrated in the accompanying drawings and described below, since the embodiments of the present invention can be variously modified in many different forms. While the present invention will be described in conjunction with exemplary embodiments thereof, it is to be understood that the present description is not intended to limit the present invention to those exemplary embodiments. On the contrary, the present invention is intended to cover not only the exemplary embodiments, but also various alternatives, modifications, equivalents and other embodiments that may be included within the spirit and scope of the present invention as defined by the appended claims.

Throughout the drawings, the same reference numerals will refer to the same or like parts.

It will be understood that, although the terms “first”, “second”, etc. may be used herein to describe various elements, these elements should not be limited by these terms. These terms are only used to distinguish one element from another.

For example, a first element could be termed a second element, and, similarly, a second element could be termed a first element, without departing from the scope of the exemplary embodiments of the present invention. As used herein, the term “and/or” includes any and all combinations of one or more of the associated listed items.

Unless otherwise defined, all terms including technical and scientific terms used herein have the same meaning as commonly understood by one of ordinary skill in the art to which the present invention belongs.

It will be further understood that terms, e.g., those defined in commonly used dictionaries, should be interpreted as having a meaning that is consistent with their meaning in the context of the relevant art and are not to be interpreted as having an idealized or overly formal sense unless expressly so defined herein.

Hereinafter, a detailed description will be given of a Raman edge filter in a deep-UV range and a method of manufacturing the same, according to embodiments of the present invention with reference to the appended drawings.

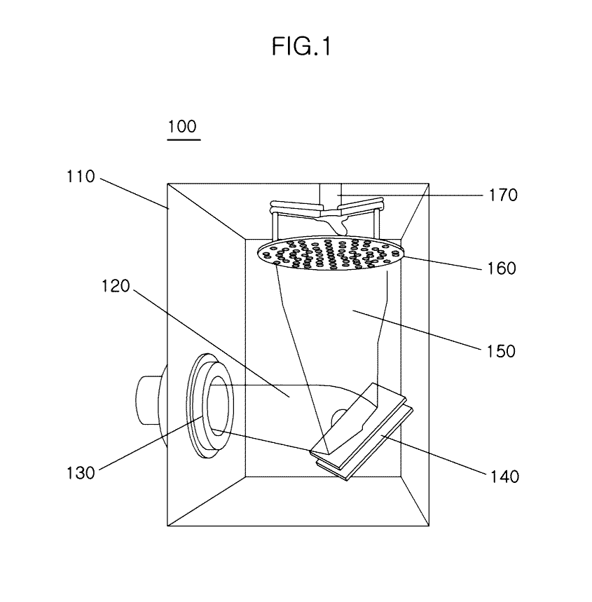

FIG. 1 illustrates a typical IBS device. In the IBS device 100 shown in FIG. 1, when charged gas particles (e.g. Ar, O₂) having specific energy collide with the surface of a sputtering target 140, atoms 150 are ejected from the surface through momentum transfer and are then deposited on a substrate mounted to a substrate holder 160. In a vacuum chamber 110, an ion beam 120 from an ion beam source 130 is incident on the target 140 at an incline, and thus, a Kaufman ion gun for use in ion beam sputtering is provided together with an oval-shaped grid to prevent the ion beam that reaches the surface of the sputtering target 140 from reaching portions other than the target. The substrate holder 160 is rotated by a rotary drive 170, so that the atoms 150 are uniformly deposited on the substrate.

The initial deposition pressure is as low as 10⁻⁶ torr and thus there is no concern about the penetration of impurities into the thin film. The atoms deposited through IBS (Ion Beam Sputtering) have high deposition energy corresponding to tens of eV or more, compared to other deposition methods, whereby the deposited thin film is denser and has higher adhesion.

IBS is a process in which an accelerated ion beam is applied to the target to sputter the target material, which is then deposited on an upper substrate. A typical example of the gas for an ion beam includes Ar, but the target material is an oxide and thus needs O₂ in air, and the Ar-to-O₂ ratio is optimally set to 1:2 through preliminary testing. The ion beam source is an ion source using high-frequency discharge, and the extraction voltage may range from 0V to about 24V.

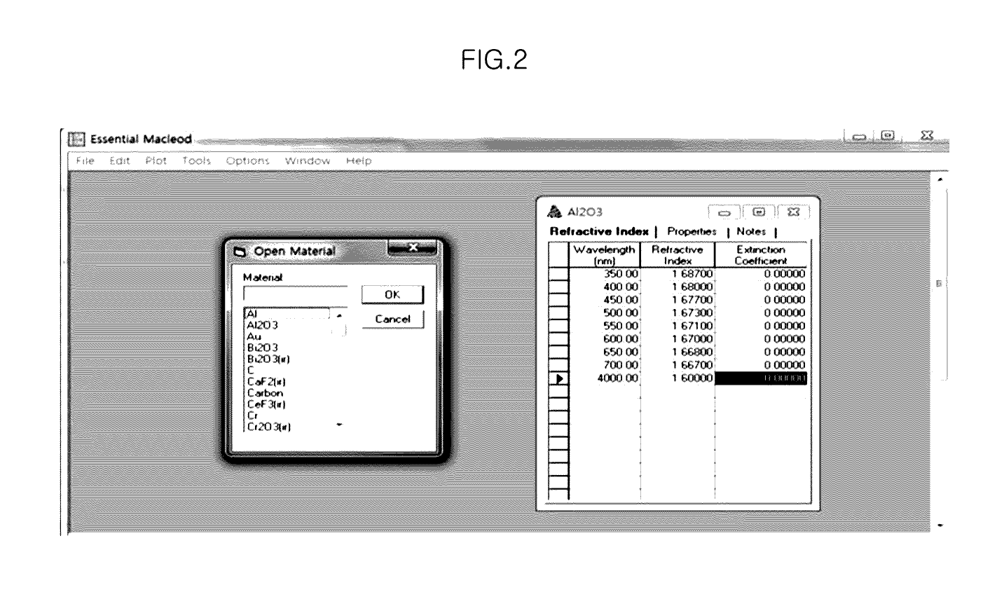

FIG. 2 illustrates the screen for choosing the thin-film material according to an embodiment of the present invention. With reference to FIG. 2, useful as a thin-film (i.e. coating) material in the deep-ultraviolet ray (UV) range of interest, a high-refractive-index dielectric material may include LaF₃, HfO₂, Al₂O₃, and Sc₂O₂, and a low-refractive-index dielectric material may include SiO₂, MgF₂, and Na₃AlF₆. Taking into consideration the coating process through IBS (Ion Beam Sputtering) according to an embodiment of the present invention, Al₂O₃ and SiO₂ are adopted. The optical constants of two materials are applied to a design made using “Essential Macleod” software with the goal of depositing Al₂O₃ and SiO₂.

Although an ion gun for use in ion beam-assisted deposition for coating deposition has an ion accelerator grid to thus make high-energy ions, a Kaufman-type ion beam having low ion current density may be utilized.

The coating is configured such that, to perpendicularly form a slope from an inhibition zone to a transmission zone, the repeating number for a coating is determined to be high, and thus a design formula is set based on air/(0.5HL0.5H)̂40(0.54HL0.54H)̂61/substrate. In the design formula, 0.5 is λ/8, 0.54 is λ/8 (1.08), H is a dielectric material with a high index of refraction, L is a dielectric material with a low index of refraction, ̂X are the number of repetition which the H and the L are stacked alternately after a first layer stacked with the H. In the design formula, for example, H=Al₂O₃ and L=SiO₂. The optical constants of two materials are determined using the Essential Macleod software and then applied to the design.

Al₂O₃ and SiO₂ are deposited using ion beam sputtering. In order to satisfy a desired coating specification using the design formula, a transmittance target value of the Essential Macleod software is automatically calculated. Furthermore, ripples of the transmission zone are alleviated using the Optimac function of the Essential Macleod software for setting the coating thickness, thus effectively removing the irradiation light source wavelength (e.g. about 213 nm) in the deep-UV range. Also, the Raman edge filter functions to transmit the Raman scattered light.

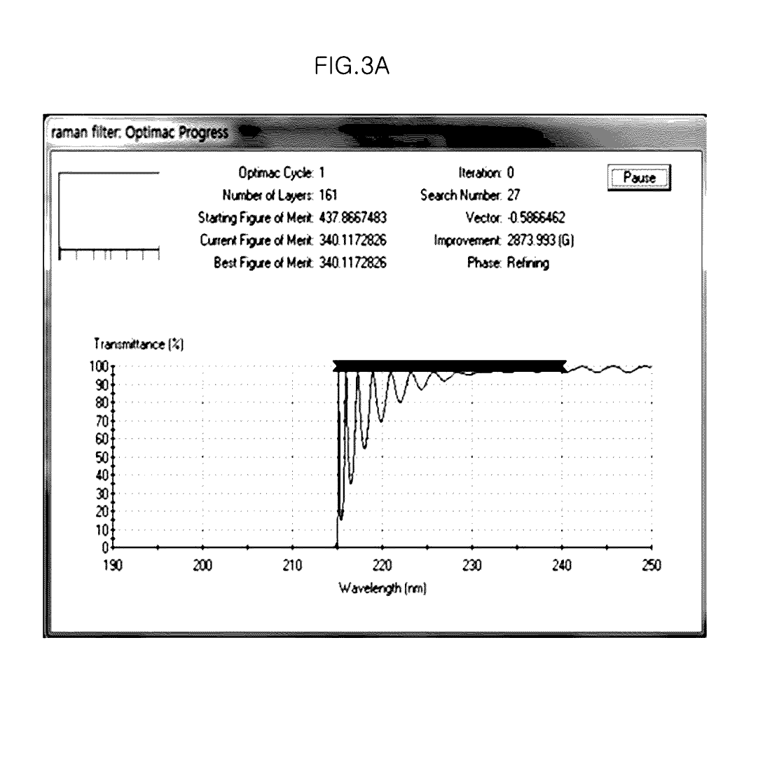

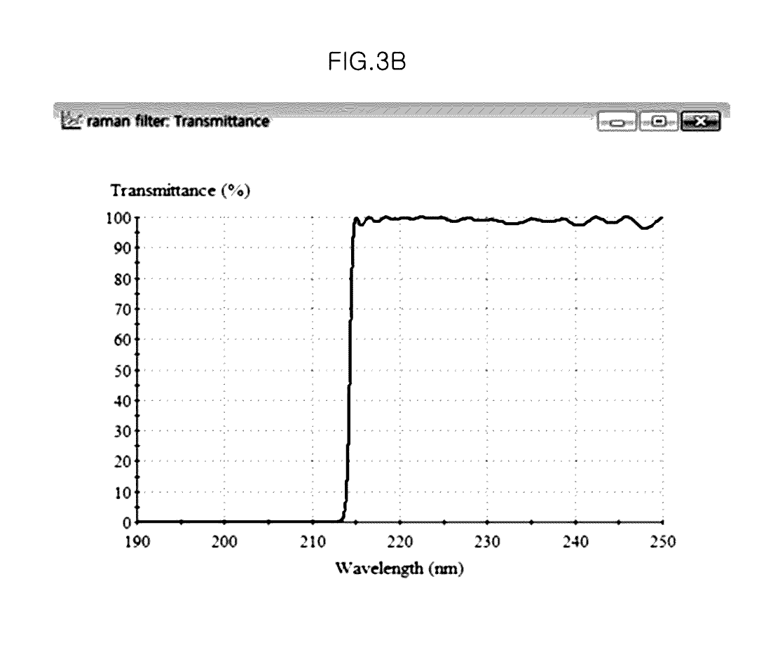

FIGS. 3A and 3B are graphs illustrating the results of optimization of a design for a coating for the Raman edge filter. In FIG. 3A, the performance is graphed when the coating design for the Raman edge filter using Al₂O₃ and SiO₂ is based on air/(0.5HL0.5H)̂40 (0.54HL0.54H)̂61/substrate (H=Al₂O₃, L=SiO₂) as the coating formula. In order to remove the ripples in the transmission zone, an Optimac function is used, so that the transmittance target value of the Essential Macleod software is automatically calculated, whereby the coating thickness is set.

As illustrated in FIG. 3B, the design of FIG. 3A is optimized, and the ripples in the transmission range are alleviated, thereby exhibiting the performance of the Raman edge filter, which plays a role in transmitting Raman scattered light while the irradiation light source wavelength (about 213 nm) in the deep-UV range is effectively removed.

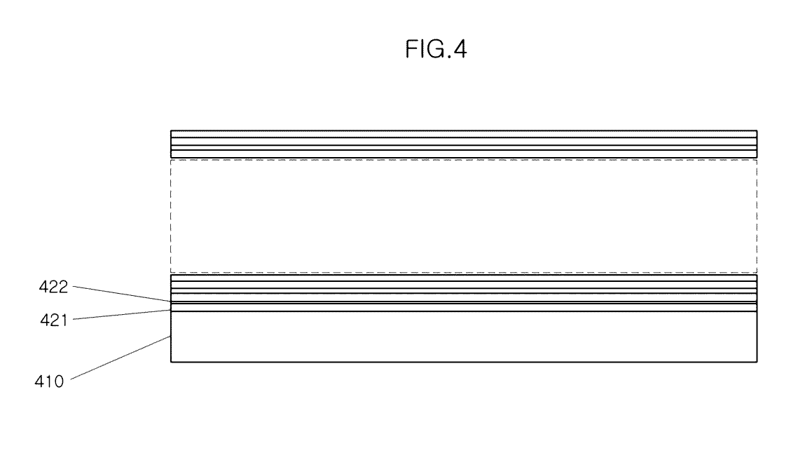

FIG. 4 illustrates the coating design for a Raman edge filter according to an embodiment of the present invention. As illustrated in FIG. 4, when the repeating number P is increased in the coating design for the Raman edge filter, the slope from the inhibition zone to the transmission zone is perpendicularly formed. This is because the number of layers in the coating is increased. Since the desired coating specification cannot be satisfied based only on such a fundamental formula, the ripples of the transmission zone are alleviated using the Optimac function of the Essential Macleod software.

Based on the results of optimal design, the coating is designed to have the number of layers and the thickness shown in FIG. 4. With reference to FIG. 4, the high-refractive-index dielectric material layer 421 and the low-refractive-index dielectric material layer 422 are repeatedly formed by turns on a molten silica substrate 410 until the number of layers reaches the repeating number P. As such, the number of layers for the coating is 203, and the thickness of the coating is 6100 nm. The high-refractive-index dielectric material layer 421 is formed of Al₂O₃, and the low-refractive-index dielectric material layer 422 is formed of SiO₂.

Since the material is absorbed or scattered depending on the type of coating process in the deep-UV range, durability and bondability of the coating are increased using IBS, and the Ar-to-O₂ ratio is adjusted to minimize the absorption, thereby preventing the transmittance from decreasing.

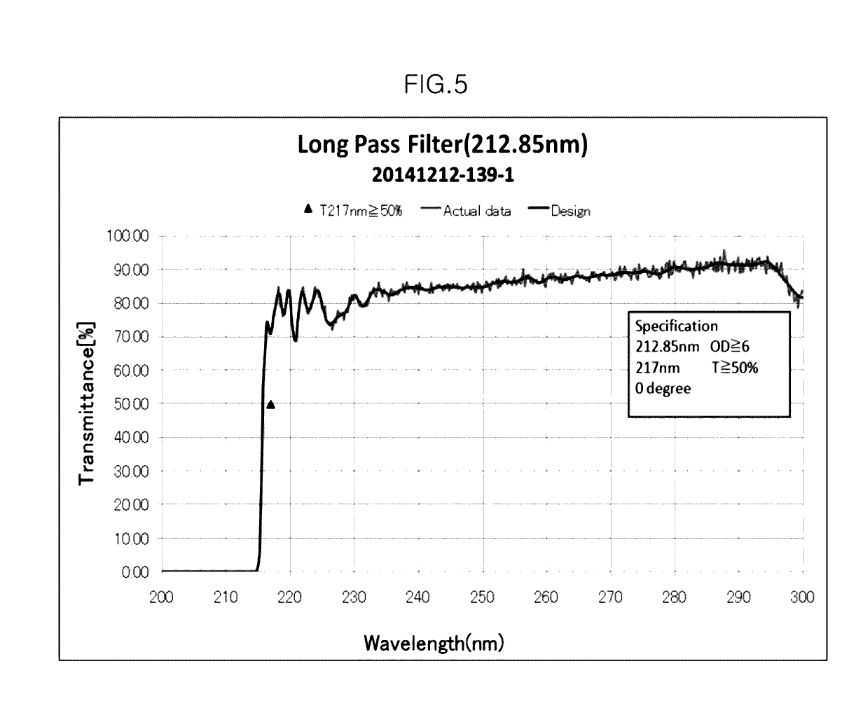

FIG. 5 is a graph illustrating the performance of the Raman tilter according to an embodiment of the present invention. As illustrated in FIG. 5, based on the results of performance of the Raman filter of FIG. 4, the filter is designed and manufactured so as to increase durability and bondability of the coating using IBS and to minimize the absorption by adjusting the Ar-to-O₂ ratio, and may exhibit a strong effect of blocking Rayleigh scattering of a laser beam. Therefore, the Raman filter may be applied to a Raman spectrometer in the deep-UV range (213 nm).

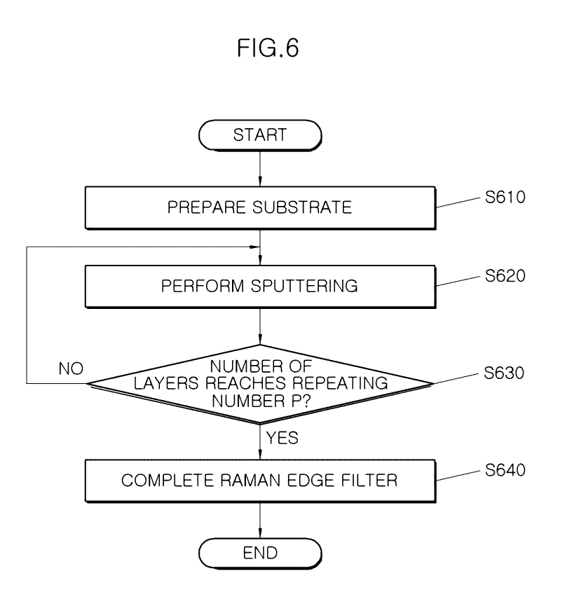

FIG. 6 is a flowchart illustrating the process of manufacturing the Raman edge filter according to an embodiment of the present invention. As illustrated in FIG. 6, a high-refractive-index dielectric material, Al₂O₃, and a low-refractive-index dielectric material, SiO₂, which are chosen coating materials, are mounted on a sputtering target 140 (FIG. 1) in a vacuum chamber 110 (FIG. 1), and the substrate 410 (FIG. 4) to be coated is mounted to a substrate holder 160 (FIG. 1) (S610).

Thereafter, the inside of the vacuum chamber 110 is evacuated using a vacuum pump. The initial vacuum level is set to about 5×10⁻⁶ torr and the coating process begins to be carried out. Using Ar and O₂ as ionization gases, Al₂O₃ and SiO₂ are sputtered by turns, and the substrate holder 160 is rotated to form a uniform coating (S620). As such, the deposition rate is 0.8 (Å/sec) for Al₂O₃ and 2 (Å/sec) for SiO₂, but the present invention is not limited thereto, and Al₂O₃ may be deposited at a rate of about 0.4 to 1.1 (Å/sec) and SiO₂ may be deposited at a rate of about 1 to 3 (Å/sec).

The sputtering is performed a number of times equal to a predetermined repeating number P, whereby a Raman edge filter is manufactured (S630, S640). The repeated deposition of two materials is carried out such that the slope at the boundary between the transmission region and the reflection region of light is formed to be perpendicular so as to enable the two regions to be distinguished from each other.

The repeated deposition process is performed such that an ion source is applied to the Al₂O₃ target so that the target is sputtered through collisions with ions, after which the SiO₂ target is located toward the ion source so that sputtering is performed in the same manner. This sputtering process is repeated 203 times. Here, the repeating number P is set to 203 as an example, but the present invention is not limited, and the repeating number P may vary depending on the properties of the Raman edge filter.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A method of manufacturing a Raman edge filter in a deep-ultraviolet ray (UV) range, comprising:
providing a molten silica substrate, a high-refractive-index dielectric material, and a low-refractive-index dielectric material in a vacuum chamber;
evacuating an inside of the chamber, and
repeatedly depositing the high-refractive-index dielectric material and the low-refractive-index dielectric material by turns on a surface of the molten silica substrate using ion beam sputtering (IBS) until a number of deposited layers reaches a predetermined repeating number such that an irradiation light source wavelength in a deep-UV range is removed and light at a wavelength equal to or greater than the irradiation light source wavelength is transmitted.

2. The method of claim 1, wherein the high-refractive-index dielectric material comprises any one selected from among LaF₃, HfO₂, Al₂O₃, and Sc₂O₂, and the low-refractive-index dielectric material comprises any one selected from among SiO₂, MgF₂, and Na₃AlF₆.

3. The method of claim 1, wherein the repeating number is about 200 or more.

4. The method of claim 1, wherein the irradiation light source wavelength has an optical density (OD) of about 6 or more, and a transmittance of about 50% or more at about +4 nm.

5. The method of claim 1, wherein an ion beam of the ion beam sputtering is a Kaufman-type ion beam.

6. The method of claim 1, wherein the irradiation light source wavelength in the deep-UV range is about 213 nm.

7. The method of claim 1, wherein the repeatedly depositing is performed in a manner in which the high-refractive-index dielectric material is deposited at a deposition rate of about 0.4 to 1.0 (Å/sec) and the low-refractive-index dielectric material is deposited at a deposition rate of about 1 to 3 (Å/sec).

8. A Raman edge filter in a deep-UV range, comprising:
a molten silica substrate;
a high-refractive-index dielectric material layer formed on a surface of the molten silica substrate; and
a low-refractive-index dielectric material layer formed on a surface of the high-refractive-index dielectric material layer,
wherein the high-refractive-index dielectric material layer and the low-refractive-index dielectric material layer are repeatedly deposited by turns on the surface of the molten silica substrate using ion beam sputtering until a number of deposited layers reaches a predetermined repeating number such that an irradiation light source wavelength in a deep-UV range is removed and light at a wavelength equal to or greater than the irradiation light source wavelength is transmitted.
